(19) United States
(12) Patent Application Publication
(10) Pub. No.: US 2016/0088939 A1
(43) Pub. Date: Mar. 31, 2016

(54) RETROFITABLE HANGING FRAME

(71) Applicant: Karen Y. Lamb, Belleville, MI (US)

(72) Inventor: Karen Y. Lamb, Belleville, MI (US)

(21) Appl. No.: 14/938,051

(22) Filed: Nov. 11, 2015

Related U.S. Application Data
(63) Continuation-in-part of application No. 13/671,728, filed on Nov. 8, 2012, now abandoned.

(51) Int. Cl. A47B 95/00; A47B 61/00; A47B 77/04; H05K 7/02; A47B 81/00; E06B 1/52; E06B 3/70; A47B 67/00; A47B 65/00

(52) U.S. Cl. CPC A47B 95/008; A47B 67/005; A47B 61/003; A47B 77/04; A47B 65/00; A47B 81/00; A47B 95/00; E06B 1/52; E06B 3/70; H05K 7/02

(57) ABSTRACT

A retrofitable inverted-U-shaped frame is provided configured to hang over a top of a panel. The inverted-U-shaped frame includes a closed end of the inverted-U-shaped frame configured to hang upon the top of the panel, a first elongated support member projecting downward from the closed end to a middle portion of the panel and configured to hang along a first side of the panel, and a second elongated support member projecting downward from the closed end to the middle portion of the panel and configured to hang along a second side of the panel. The elongated support members are each configured to support an attachment.

### CROSS REFERENCE TO RELATED APPLICATIONS

This disclosure is a continuation in part of U.S. application Ser. No. 13/671,728 filed on Nov. 8, 2012, which is hereby incorporated by reference.

### TECHNICAL FIELD

This disclosure is related to providing retrofitable mounting members from each side of a tall panel. In one embodiment, this disclosure is related to providing improved and increased access to handicap restroom facilities, and in particular providing an ability to almost instantly install handrails in a toilet stall.

### BACKGROUND

The statements in this section merely provide background information related to the present disclosure. Accordingly, such statements are not intended to constitute an admission of prior art.

Panels are used in a wide variety of housing and building purposes. A panel can serve as a door, mounted on one side to a hinge or plurality of hinges. A panel can serve as a partition wall, for example, in a restroom, dividing one toilet stall from another toilet stall. Panels divide one space from another space.

Restroom facilities are required for use in either public or private places. A restroom can include stalls wherein a toilet fixture is shielded by partition walls, providing the person using the toilet fixture with privacy. Stalls are provided with handrails affixed to the walls of the stall, thereby permitting a person to lift him or herself onto and off of the toilet fixture. Such handrails are provided, for example, in handicap-equipped stalls, permitting a person using a wheelchair to move from the wheelchair to the toilet fixture and back to the wheel chair.

Restrooms can be required in public places to meet standards or building codes required by law. A minimum number or percentage of stalls to be equipped with handrails can be mandated. Refurbishing an older building to new building codes can require installation of handrails to conform with handicap accessibility requirements.

Whether a building and the facilities therein adequately serve the population of the building depends upon the demographics of the building. Demographics can change. The United States includes a Baby Boom generation that, as it ages, will increase a share of the public that will have special needs. A building that was adequate while the Baby Boomers were middle aged can be inadequate as the generation reaches advanced ages. Wherein a single handicap stall out of three might have been sufficient at one point, it can be advantageous to make all three stalls equipped for increased accessibility as the demographics change.

Further, behavior patterns show that some able-bodied persons prefer to use stalls with handrails, in particular, where cleanliness is an issue. in such a situation, a person with special needs may find the stalls equipped with handrails to frequently be in use while other non-equipped stalls are open.

A building can meet minimum requirements for accessibility, but a special use of the building can create shortages in restroom accessibility. A convention attracting a large number of attendees using wheelchairs can cause shortages and long lines in the restroom for the few handrail equipped stalls. A commercial building rededicated to an association assisting and frequented by individuals in wheelchairs, based upon the increased demand for handicap equipped stalls, can be deficient in handrail equipped stalls. Not every stall can be equipped with handrails attached only to the partition walls. Partition walls may not include sufficient structural strength to be used to support a person being repositioned to and from a toilet fixture. The hardware used to position the partition walls may not be configured for the added weight that use of handrails requires. Some stalls are narrow. A building owner may not want permanent handrails installed to every stall for a single upcoming event in light of the space that the handrails will take up in the narrow stalls when the building returns to a normal usage where the originally installed handicap access stalls is sufficient.

### SUMMARY

A retrofitable inverted-U-shaped frame is provided configured to hang over a top of a panel. The inverted-U-shaped frame includes a closed end of the inverted-U-shaped frame configured to hang upon the top of the panel, a first elongated support member projecting downward from the closed end to a middle portion of the panel and configured to hang along a first side of the panel, and a second elongated support member projecting downward from the closed end to the middle portion of the panel and configured to hang along a second side of the panel. The elongated support members are each configured to support an attachment.

### BRIEF DESCRIPTION OF THE DRAWINGS

One or more embodiments will now be described, by way of example, with reference to the accompanying drawings, in which:

FIG. 1 illustrates in cross-section an exemplary retrofitable handrail with a single handrail member installed to a restroom stall, in accordance with the present disclosure;

FIG. 2 illustrates the retrofitable handrail of FIG. 1 in a schematic view, in accordance with the present disclosure;

FIG. 3 illustrates an exemplary retrofitable handrail for use in side by side stalls, in accordance with the present disclosure;

FIG. 4 illustrates an exemplary embodiment of attachment hardware that can be used to attach a handrail to support members of a retrofitable handrail, in accordance with the present disclosure;

FIG. 5 illustrates an exemplary adjustable support member of a retrofitable handrail, in accordance with the present disclosure;

FIG. 6 illustrates an exemplary retrofitable handrail made of tubes with a floor support member, in accordance with the present disclosure;

FIG. 7 illustrates an exemplary adjustable floor support member, in accordance with the present disclosure;

FIG. 8 illustrates an exemplary additional embodiment for a hanging support and an associated attachment member, in accordance with the present disclosure;

FIG. 9 illustrates an exemplary retrofitable handrail configured to provide handrails in two adjacent stalls, with support members that closely follow the shape of the partition wall, in accordance with the present disclosure;

FIG. 10 illustrates an exemplary retrofitable handrail installed to a partition in a restroom, illustrating various aspects of the handrail, in accordance with the present disclosure;

FIG. 11 illustrates an exemplary shallow inverted-U-shaped member being tilted upon a wall top, the member potentially being dislodged from the wall, in accordance with the present disclosure;

FIG. 12 illustrates an exemplary inverted-U-shaped member being tilted upon a wall top, the member including elongated support members on both sides of the wall preventing the inverted-U-shaped member from being dislodged from the wall by the tilting, in accordance with the present disclosure;

FIG. 13 illustrates an exemplary hanging frame that can be used to retrofit a closet or shower door panel with a towel rack, in accordance with the present disclosure;

FIG. 14 illustrates an exemplary hanging frame that can be used to retrofit a closet or shower door panel with features on both sides of the door panel, in accordance with the present disclosure; and

FIG. 15 illustrates an exemplary configurable inverted-U-shaped frame including elongated support members configured to extend down both sides of a panel and generic attachment portions attached to each elongated support member configured to receive modularized attachments, in accordance with the present disclosure.

### DETAILED DESCRIPTION

Panels are provided for use in homes and other buildings. Such panels can be used to divide one portion of a room from another portion of a room, for example, for privacy reasons. Examples include restroom panel partition walls and cubicles in an office building. Panels can be used to provide doors which can be opened and closed. A retrofitable inverted-U-shaped frame system is disclosed enabling a person to accessorize a panel, with an attachment member hanging from a top of the panel and elongated support members extending down one side or both sides of the panel, enabling support objects such as handrails, towel racks, and baskets to be hung at some level correspond to a middle portion of the panel. Panelized doors can include a entry door separating one room from another room. Panelized doors can include a cabinet door on the front of a storage cabinet or armoire. Panelized doors can include a shower door providing a closeable enclosure for a shower stall. Panelized doors can include a closet door. A panelized privacy wall in a restroom stall is configured to prevent a person of average height in a population, when standing, from viewing into a neighboring stall or especially viewing the toilet in the neighboring stall. In one embodiment, a top of such a privacy wall is at least sixty six inches above a floor surface, although the top can be at greater heights from the floor surface.

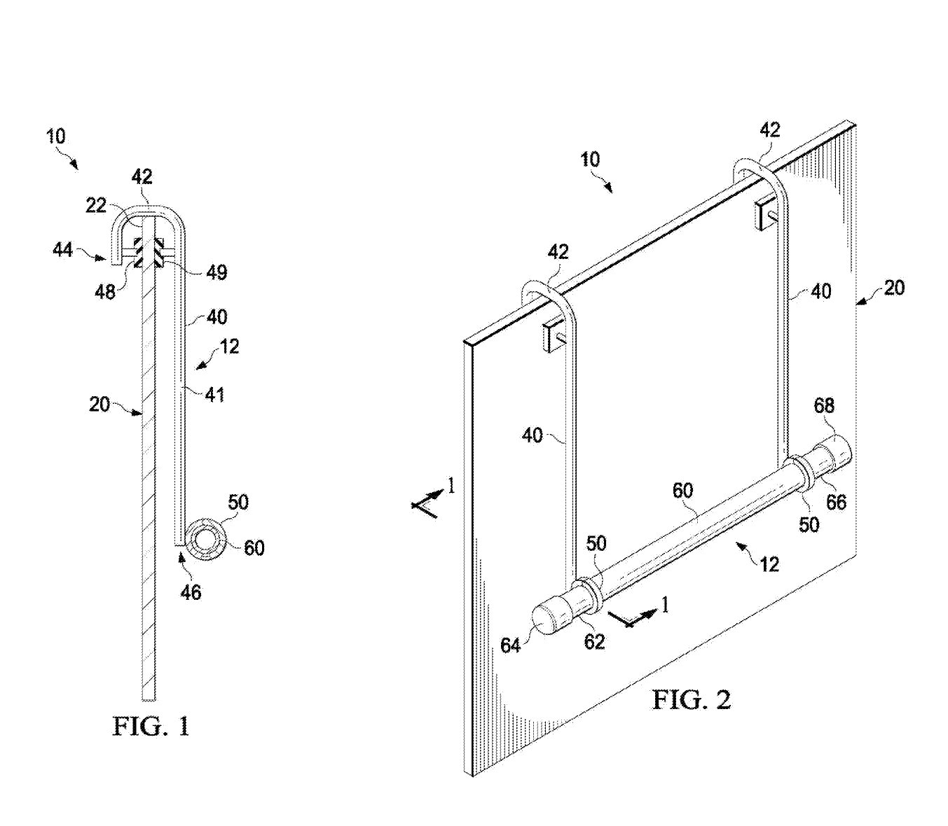

Referring now to the drawings, wherein the showings are for the purpose of illustrating certain exemplary embodiments only and not for the purpose of limiting the same, FIG. 1 illustrates in cross-section an exemplary retrofitable handrail installed to a restroom stall. Configuration 10 includes a retrofitable handrail 12 including hanging support 40 installed to a restroom stall partition wall 20. Hanging support 40 includes support member 41, attachment member 42 securing hanging support 40 to a top 22 of partition wall 20, and handrail member or handrail 60 secured to end 46 of support member 41 with handrail bracket 50. According to one embodiment, attachment member 42 can include gripping bracket 48 attached to end 44 of attachment member 42 and gripping bracket 49 attached to support member 41. One or both of gripping brackets 48 and 49 can be adjustable to provide a clamping function to the top 22 of the partition wall 20. In another embodiment, a suction device or suction devices can be used in place of or in addition to the gripping brackets in order to secure the retrofitable handrail to the partition wall.

FIG. 2 illustrates the retrofitable handrail of FIG. 1 in a schematic view. The exemplary embodiment of configuration 10 includes retrofitable handrail 12 including two hanging supports 40 and hand rail 60, handrail 12 being attached to partition wall 20. Each hanging support 40 includes an attachment member 42. Handrail 60 is attached to each of the hanging supports 40 with handrail brackets 50. A handrail 60 can be a straight bar as illustrated in FIG. 2. In other embodiments, a handrail can be curved, for example with ends of the bar curving toward the partition wall. Exemplary handrail 60 is illustrated with an end cap 64 installed to first end 62 and end cap 68 installed to second end 66.

Retrofitable handrail 12 can more stable if a support or bracket proximate to handrail member 60 comes into contact with partition wall 20. Wherein handrail 60 is straight, the hanging support 40 can come into contact with the partition wall or a bracket or tab can otherwise extend from retrofitable handrail 12 to contact the partition wall 20 near handrail 60 to stabilize the handrail. In another embodiment, wherein the handrail member is curved, the end can come into contact with the partition wall to provide stability.

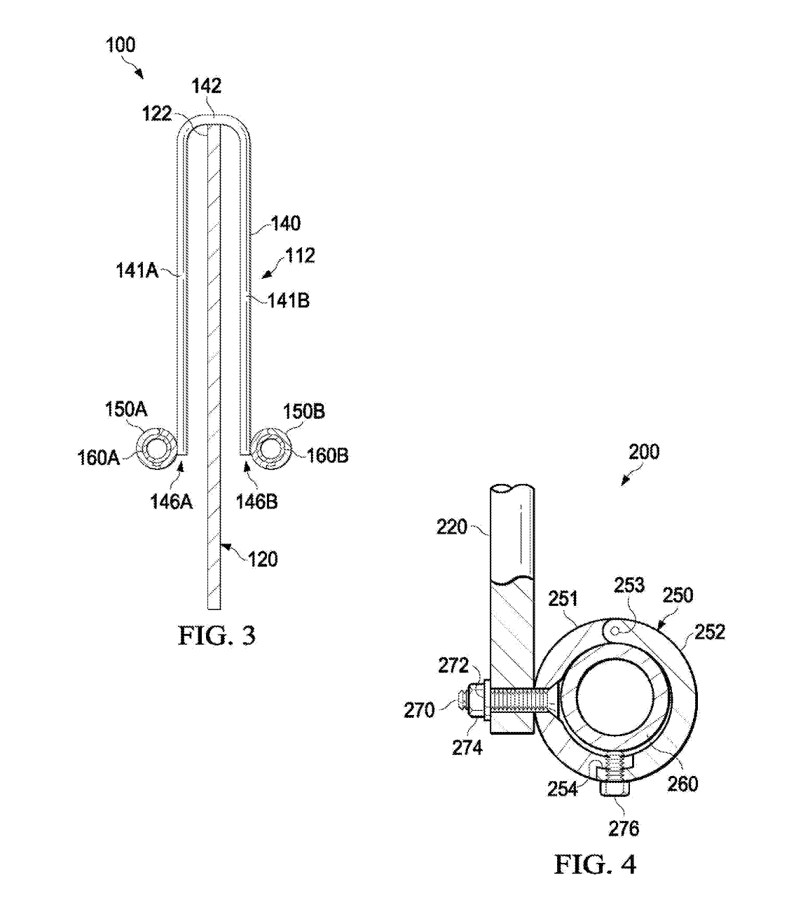

FIG. 3 illustrates an exemplary retrofitable handrail for use in side by side stalls. Retrofitable handrail 112 is installed to partition wall 120 and includes hanging support 140, a first handrail 160A, and a second handrail 160B. Hanging support 140 includes a first support member 141A and a second support member 141B. Handrail bracket 150A attaches handrail 160A to first support member 141A at end 146A. Handrail bracket 150B attaches handrail 160B to second support member 141B at end 146B. Hanging support 140 further includes curved section 142 which comes into contact with top 122 of partition wall 120. Curved section 122 can optionally include brackets or can be fitted to grip or located to top 122 and prevent hanging support 140 from shifting. According to one embodiment including two sets of support members on either side of a partition wall, two curved sections 122 can be first and second attachment members, connecting or resting upon to the top of wall 122, and support members on either side of wall 122 can be first, second, third, and fourth support members.

FIG. 4 illustrates in cross-section an exemplary embodiment of attachment hardware that can be used to attach a handrail to support members of a retrofitable handrail. Handrails can be attached to support members according to a number of attachment methods. Examples are provided herein for brackets that can be used to attach the handrail to a support member, but these examples are intended to be non-limiting exemplary embodiments. Configuration 200 includes support member 220, handrail 260, and handrail bracket 250. Exemplary handrail bracket 250 includes first bracket half 251 and second bracket half 252 joined at hinge 253 by and exemplary rivet. First bracket half 251 includes a countersunk hole for bolt 270, which fastens handrail bracket 250 to support member 220 with washer 272 and nut 274. Second bracket half 252 is secured around handrail 260 with screw 276 configured to secure bracket joint 254 and further to securingly press against handrail 260. According to one embodiment, handrail 260 includes a hole to match with screw 276 to further secure the handrail—screw 276 can fastened to the matching hole in handrail 260 to prevent forward and backward movement of the handrail within the bracket. The bracket configuration of FIG. 4 is exemplary, a number of bracket configurations or attachment methods are envisioned for attaching the handrail to the support member, and the disclosure is not intended to be limited to the particular examples provided herein. Hinge 253 and screw 276, enabling adjustment of or interchangeable handrails, permit increased flexibility of installation, retrofitting, or adjustment of the handrail based upon a need of a particular restroom facility instead of providing a handrail as a one size fits all configuration.

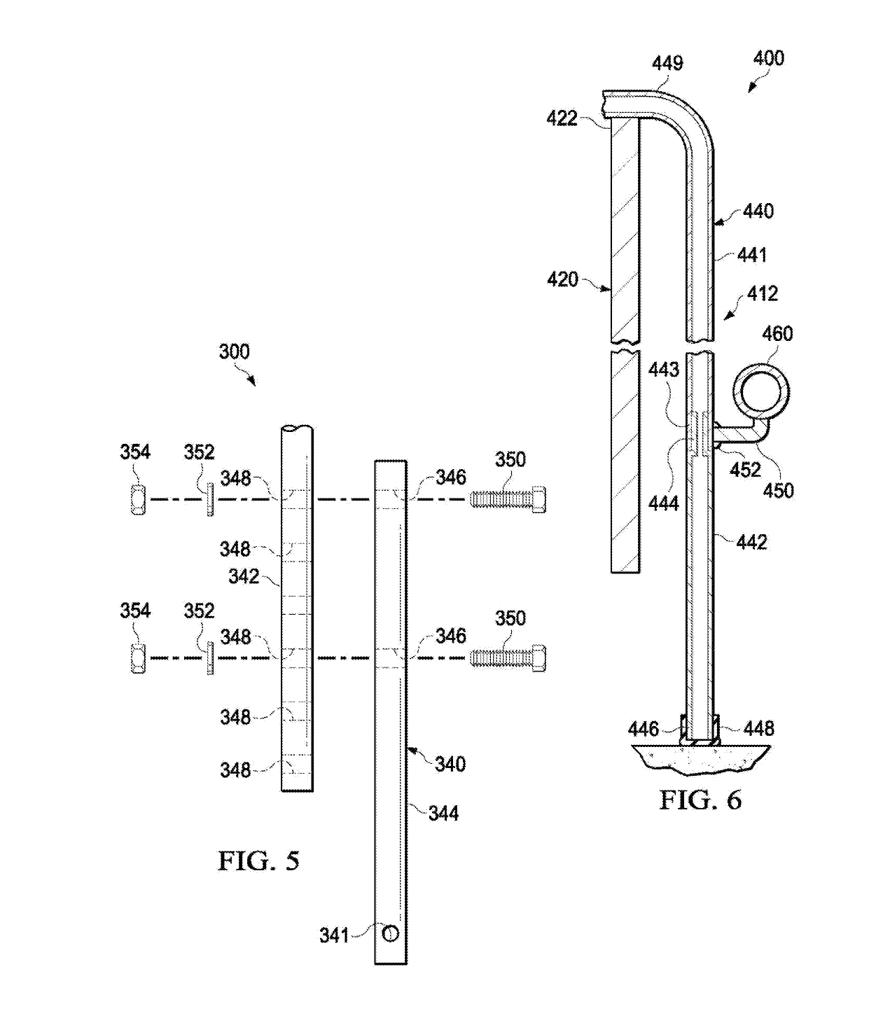

FIG. 5 illustrates an exemplary adjustable support member of a retrofitable handrail. Partition walls can have different heights. By using an adjustable support member, the handrail of a retrofitable handrail can be configured to a desired height. Configuration 300 includes support member 340 including a first portion 342 and a second portion 344. Support member 340 further includes hole 341 for attachment of a handrail. Second portion 344 includes two through-holes 346. First portion 342 includes several through-holes 348. Bolts 350 can be fitted to through-holes 346, and first portion 342 and second portion 344 can be vertically adjusted, such that bolts 350 go through two through-holes 348 and the associated handrail is set to a desired height. Washers 352 and nuts 354 are used to fasten bolts 350 and secure first portion 342 to second portion 344. Use of multiple through-holes and bolts to permit adjustment of the length of support members is one exemplary method to adjust height of retrofitable handrails. In another embodiment, adjustable support members with push pin adjustments or one portion of the support member threaded into another portion of the support member can be used to provide handrails at a customized height. A number of methods to adjust height of the handrails are envisioned, and the disclosure is not intended to be limited to the particular examples provided herein. Features disclosed and illustrates in FIGS. 4 and 5 can be used on a retrofitable handrail configured for a single stall or a retrofitable handrail configured for adjoining stalls.

FIGS. 1-5 illustrate support members made of solid bars. These exemplary solid bars can be square, rectangular, round, or any other shape in cross section. The support members, handrails, and other components of the retrofitable handrail can be made of steel, aluminum, other metals, or polymers. The selected material should include sufficient structural strength to ensure that the handrail will hold up to extended use in a restroom. The material should be easy to clean and resilient to cleaning products typically used in restrooms. In another embodiment, support members can be made of hollow or tubular members.

FIG. 6 illustrates an exemplary retrofitable handrail made of tubes with a floor support member. Configuration 400 includes retrofitable handrail 412 including hanging support 440 including support member 441, floor support member 442, and handrail 460. In embodiments wherein a partition wall 420 cannot provide sufficient structural strength to support handrail 460, a retrofitable handrail 412 can be provided with a floor support member 442 providing some or all of the weight support for the retrofitable handrail 412 through contact with the floor. Support member 441 and floor support member 442 can be a one piece member. In the exemplary embodiment of FIG. 6, a two-piece configuration wherein the floor support member 442 includes a thin section 444 that can be inserted within an end 443 of support member 441 is provided to permit a modular design. Floor support member 442 can be provided as an optional construction. Floor support member 442 includes a rubber stopper 448 fitted to end 446 of floor support member 442. Handrail 460 includes handrail bracket 450. Handrail bracket 450 includes weld joint 452 wherein the bracket is welded to the support member 441. Hanging support end 449 can attach to top 422 of partition wall 420, the retrofitable handrail 412 getting some structural support from the partition wall 420, or end 449 can be suspended above top 422 with the floor support 446 providing all of the structural strength to retrofitable handrail 412.

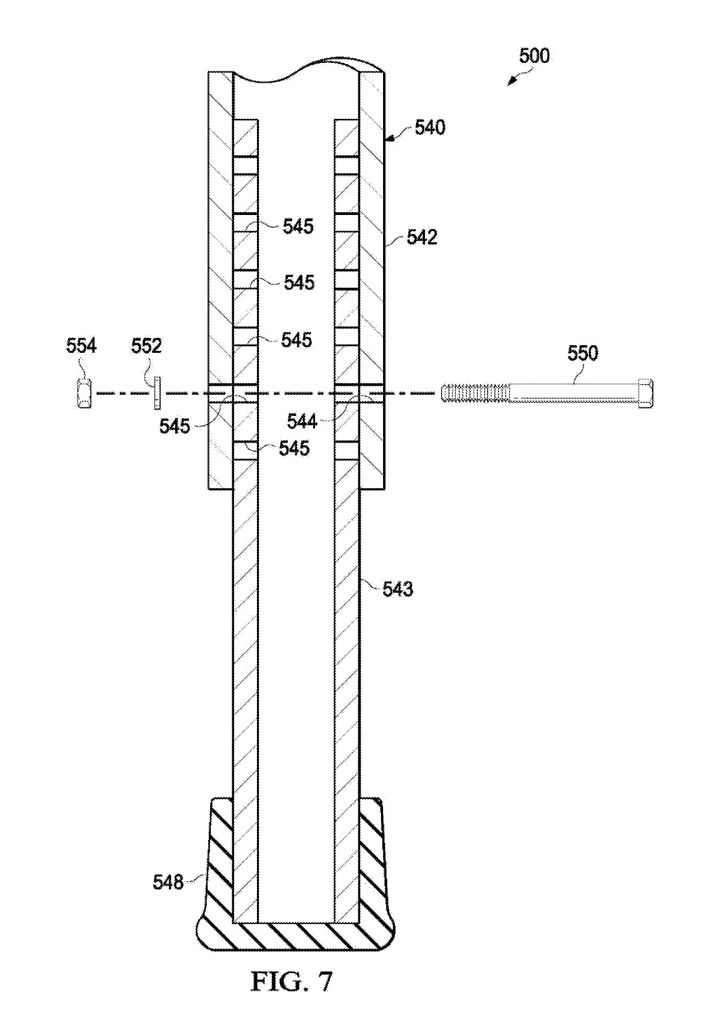

FIG. 7 illustrates an exemplary adjustable floor support member, in accordance with the present disclosure. Configuration 500 includes a floor support member 540 including a first portion 542 and a second portion 543. Both first portion 542 and second portion 543 are tubular, and the second portion 543 is sized to be fitted inside of first portion 542. The portions are vertically adjustable, wherein first portion 542 has a single through-hole 544, and second portion 543 has a plurality of through-holes 545, and bolt 550 can be inserted through through-hole 544 and a selected one of through-holes 545 to select an overall length of floor support member 540 to select a height of an associated handrail. Bolt 550 is fastened in place with washer 552 and nut 554. The method of selecting or setting the height of floor support member 540 is a non-limiting example, and other embodiments such as spring loaded push-pins being set to a one of a plurality of holes can be used to extend or compress the floor support member and adjust its length, such as are used in known adjustable canes or walker devices, are envisioned. An exemplary rubber stopper 548 is illustrated on the end of second portion 543.

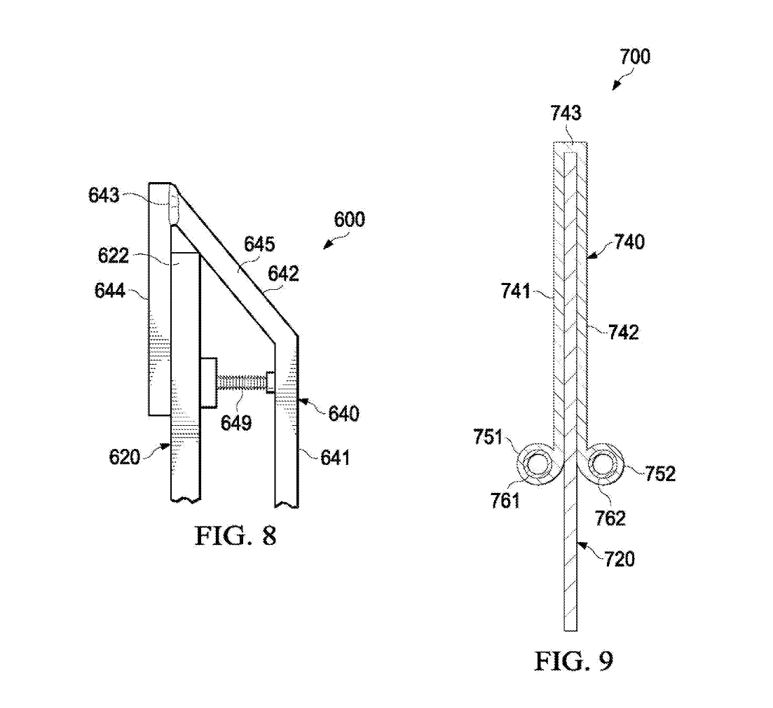

FIG. 8 illustrates an additional embodiment for a hanging support and an associated attachment member. Configuration 600 includes hanging support 640 including attachment member 642. Attachment member 642 includes a hooked section of the hanging support 640, the hooked section including angled member 645, rear support 644, and weld 643. By including angled member 645, the support member 640 will naturally seat by gravity against top 622 of partition wall 620. Rear support 644 aligns with top 622 of partition wall 622. Adjustable fastening member 649 can include a threaded adjustment feature to permit the fastening member to be tightened against wall 620. The weight of support member 640 can be carried by direct contact between top 622 and attachment member 642. In the alternative, some or all of the weight can be carried by fastening member 649 being sufficiently tightened.

FIG. 9 illustrates an exemplary retrofitable handrail configured to provide handrails in two adjacent stalls, with support members that closely follow the shape of the partition wall. Configuration 700 includes a retrofitable handrail including a hanging support 740 configured to fit closely to a profile of partition wall 720. Hanging support 740 includes a first support member 741, a second support member 742, and an attachment member 743, each configured to fit closely to partition wall 720. Handrail 761 is attached to support member 741 by handrail bracket 751, and handrail 762 is attached to support member 742 by handrail bracket 752. Construction of the various portions of configuration 700 can include welds, fasteners, or any other construction methods known in the art.

Wherein a restroom stall includes a partition wall on one side and a cinder block or otherwise permanent wall on the other side, the disclosed retrofitable hand rail can be installed on the partition wall, and a traditional handrail including fasteners affixing the handrail to the permanent wall can be utilized.

A retrofitable handrail can include two support members. A retrofitable handrail can include a single support member, for example, for use in a restroom stall that is particularly cramped. Such an embodiment can include a small handrail or a handrail embodied as a curved handle. Such an embodiment could benefit from fasteners securing the handle to the partition wall for increased stability. In another embodiment, three of more support members can be used to provide a longer handrail or to distribute the weight of the handrail over a wider section of partition wall. A handrail with a ninety degree bend can be used to provide a handrail in a restroom stall with unusual geometry.

The disclosed retrofitable handrail is easy to install and can serve as a portable or installed as needed handicap handrail system for use in public restrooms. Whereas many handicap restroom stalls require greater space to accommodate the use of wheelchairs, the disclosed device can create normally sized stalls with increased accessibility for people using canes or walkers.

According to one embodiment, the retrofitable handrail can be configured to hold a minimum of 450 pounds of weight applied to the handrail member.

The retrofitable handrail disclosed herein can be fastened to the partition wall with a screw, bolt, or other fastening method. In another embodiment, the retrofitable handrail can be configured to be applied to the partition wall without any fasteners, such that the retrofitable handrail is stably held to the wall by gravity or by gravity and an adjustable gripping member that does not include any fasteners that penetrate the surface of the partition wall. In such an embodiment, the restroom can be quickly retrofitted by hanging the retrofitable handrail upon the partition wall or locating the attachment member or members of the retrofitable handrail to the top of the partition wall.

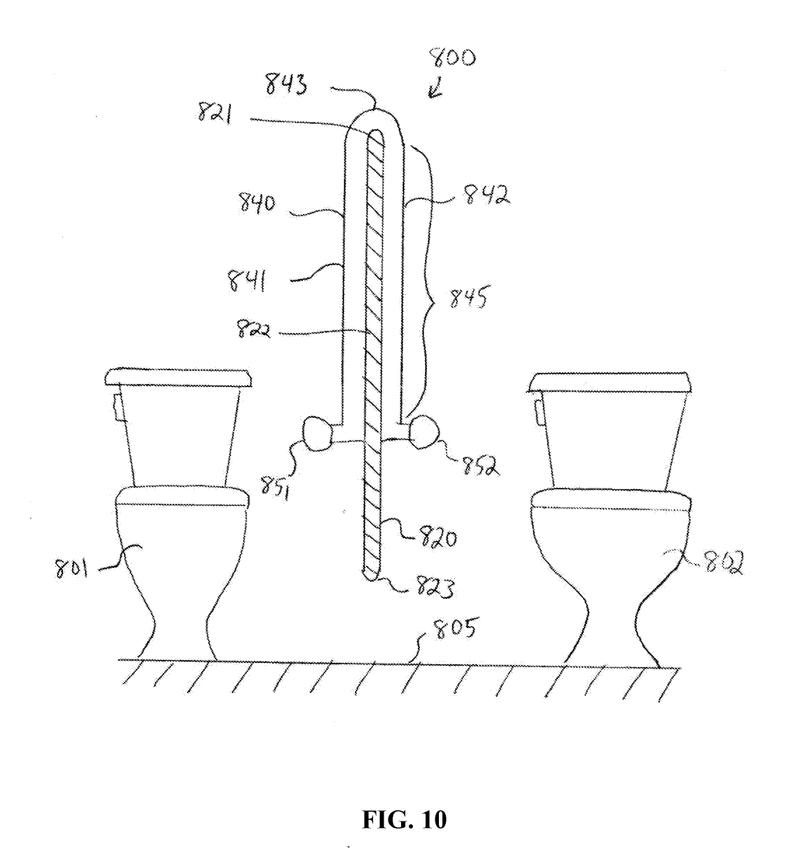

FIG. 10 illustrates an exemplary retrofitable handrail installed to a partition in a restroom, illustrating various aspects of the handrail. Configuration 800 includes a retrofitable handrail including a hanging support 840 configured to fit closely to a profile of partition wall 820. Hanging support 840 includes a first elongated support member 841, a second elongated support member 842, and an inverted U-shaped attachment member 843, each configured to fit closely to partition wall 820. Handrail 861 is attached to support member 841, and handrail 862 is attached to support member 842. Toilets 801 and 802 are illustrated on either side of partition wall 820. Floor surface 805 is illustrated.

Illustrated partition wall 820 is constructed of a panel known in the art and is typically attached to a neighboring wall and neighboring panel sections with screw fasteners. Partition wall 820 is configured to provide privacy to a person on either side of the partition wall. Wall top 821 is illustrated extending upwards to a height to provide reasonable privacy. Wall top 821 typically corresponds to a height of at least or near eye level for a typical population served by the facilities. Walls can extend to different heights. In one exemplary embodiment, wall top 821 can be five and a half feet above floor surface 805. In another exemplary embodiment, wall top 821 can extend seven or more feet above floor surface 805. Wall bottom 823 can extend all the way down to floor surface 805 but is frequently suspended some distance above floor surface 805. Middle portion 822 of wall 820 extends between wall top 821 and wall bottom 823, and includes a contiguous panel configured to prevent one from viewing from one side of wall 820 to the other side of wall 820.

Hanging support 840 of the illustrated retrofitable handrail includes inverted U-shaped attachment member 843 configured to configured to hang from wall top 821 of the partition wall. Hanging support 840 can be described as an inverted-U-shaped frame. Attachment member 843 can be described as a closed end of the inverted-U-shaped frame. Elongated support member 841 extends downwards from the closed end of the inverted-U-shaped from corresponding to the top of the partition wall to handrail 851 corresponding to middle portion 822 of the partition wall 820. Similarly, elongated support member 842 extends downwards from the closed end of the inverted-U-shaped from corresponding to the top of the partition wall to handrail 852 corresponding to middle portion 822 of the partition wall 820. Code provided by the American with Disabilities Act requires that handrails 851 and 852 be between thirty three and thirty six inches from floor surface 805. As a result, the elongated support members 841 and 842 each include a length 845 extending from a attachment member 843, situated at least at eye level for population served by the facilities and typically at least five and a half feet from floor surface 805 to the handrails which are required to be situated at a height of thirty three to thirty six inches above floor surface 805. One can say that the retrofitable handrail includes an closed end of an inverted-U-shaped frame configured to hang from a top of a privacy configured partition wall, and the retrofitable handrail including elongated support members on either side of the partition wall extending from the closed end to handrails configured to be positioned at between thirty three and thirty six inches above a floor surface.

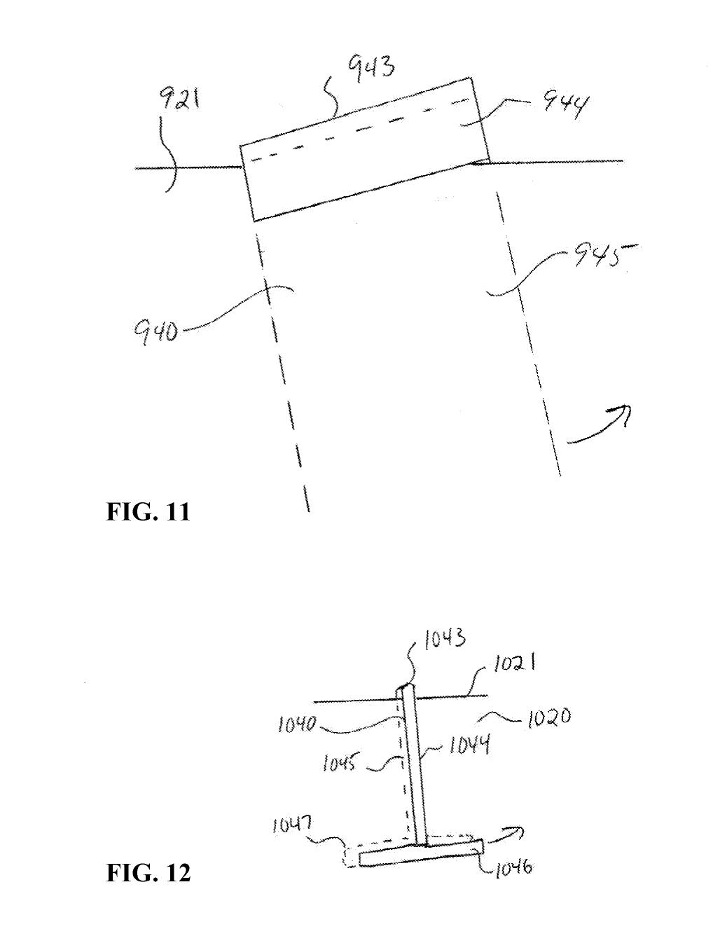

Embodiments of FIGS. 9 and 10 illustrate retrofitable handrails that include elongated members extending from the top of a privacy partition wall to handrails configured to be at a typical waist high level as defined by code. Such embodiments, with elongated members extending downwardly along both sides of a partition wall, provide enhanced stability as compared to members with only a shallow inverted-U-shaped bracket on top of the wall, for example as illustrated in FIG. 1. Without a clamping bracket holding the handrail to the top of the partition wall, the handrail would be subject to being dislodged and falling from the wall when forces parallel to the floor surface or not entirely in straight down direction are applied to the handrail system. For example, a person getting in and out a wheel chair within the restroom stall might have to push down on the handrails. However, the person may also need to apply lateral forces to the handrails, for example, to position the wheelchair. FIG. 11 illustrates an exemplary shallow inverted-U-shaped member being tilted upon a wall top, the member potentially being dislodged from the wall. Inverted-U-shaped frame 940 is configured to hang from wall top 921. Frame 940 includes shallow-U-shaped attachment member 943 including lip 944 viewed on the close side of wall top 921. Elongated support member 945 is illustrated on the far side of wall top 921. As a lateral force is applied to frame 940, attachment member 943 rocks or tilts upon the top of wall top 921 and can potentially be dislodged. Frame 940 can then fail to support the user and come falling down.

FIG. 12 illustrates an exemplary inverted-U-shaped member being tilted upon a wall top, the member including elongated support members on both sides of the wall preventing the inverted-U-shaped member from being dislodged from the wall by the tilting. Inverted-U-shaped frame 1040 is configured to hang from wall top 1021 of partition wall 1020. Frame 1040 includes elongated support member 1044 attached to U-shaped attachment member 1043 on an illustrated close side of wall 1020 and elongated support member 1045 on an illustrated far side of wall 1020. By encapsulating the wall with elongated support members 1044 and 1045 on a close and far side of wall 1020, respectively, frame 1040 is stably attached to the wall 1020 and cannot be dislodged from the wall without lifting the support members and the attached handrail members above wall top 1021. The frame of FIG. 12 provides increased stability and safety as compared to the frame of FIG. 11 in any application where lateral forces can be applied to the frame.

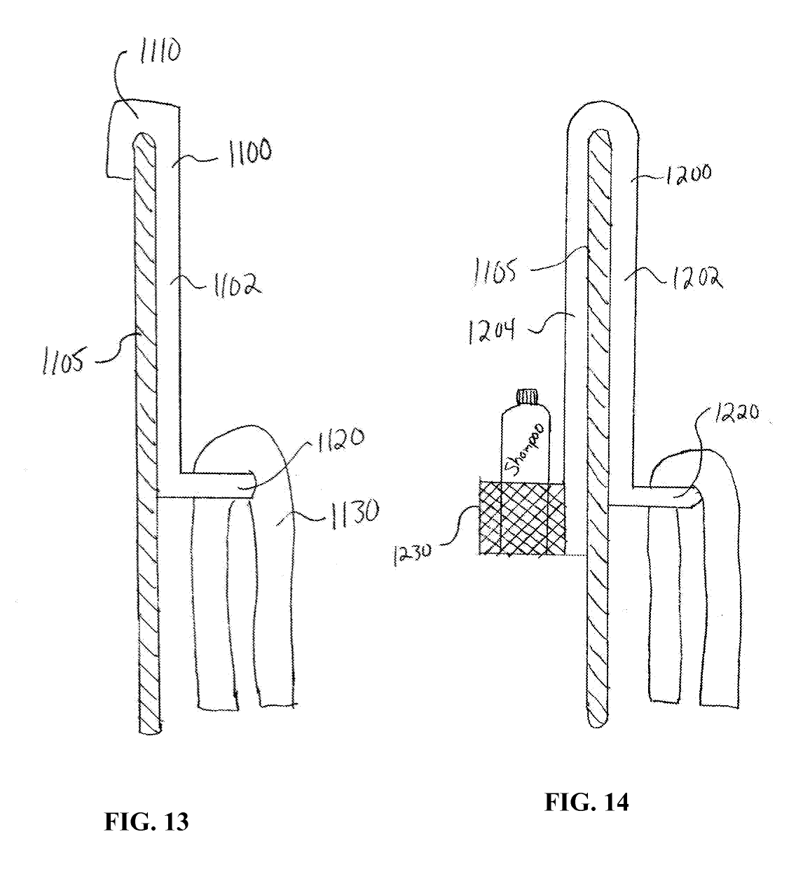

FIG. 13 illustrates an exemplary hanging frame that can be used to retrofit a closet or shower door panel with a towel rack. Inverted-U-shaped frame 1100 is illustrated, with attachment member 1110 hanging from a panel top of door panel 1105. Door panels are known in the art and are configured for a person of ordinary height to enter and leave a space without undue effort. Door panel tops according to the disclosure are anticipated to be at least five and a half feet above a corresponding floor surface. Elongated member 1102 is illustrated hanging from attachment member 1110 from the top of the door panel. Towel rack member 1120 is illustrated supporting towel 1130. Towel rack member 1120 and the elongated member 1102 are configured such that the towel rack member 1120 is situated similarly above the floor surface as the handrail members of the previous illustrations.

FIG. 14 illustrates an exemplary hanging frame that can be used to retrofit a closet or shower door panel with features on both sides of the door panel. Inverted-U-shaped frame 1200 is illustrated, with attachment member 1210 hanging from a panel top of door panel 1105. Elongated member 1202 is illustrated hanging from attachment member 1210 from the top of the door panel along a first side of the door panel, and elongated member 1204 is illustrated hanging from attachment member 1210 from the top of the door panel along a second side of the door panel. Towel rack member 1220 is illustrated connected to elongated member 1202 supporting a towel. Basket member 1230 is illustrated connected to elongated member 1204 and supporting an exemplary bottle of shampoo.

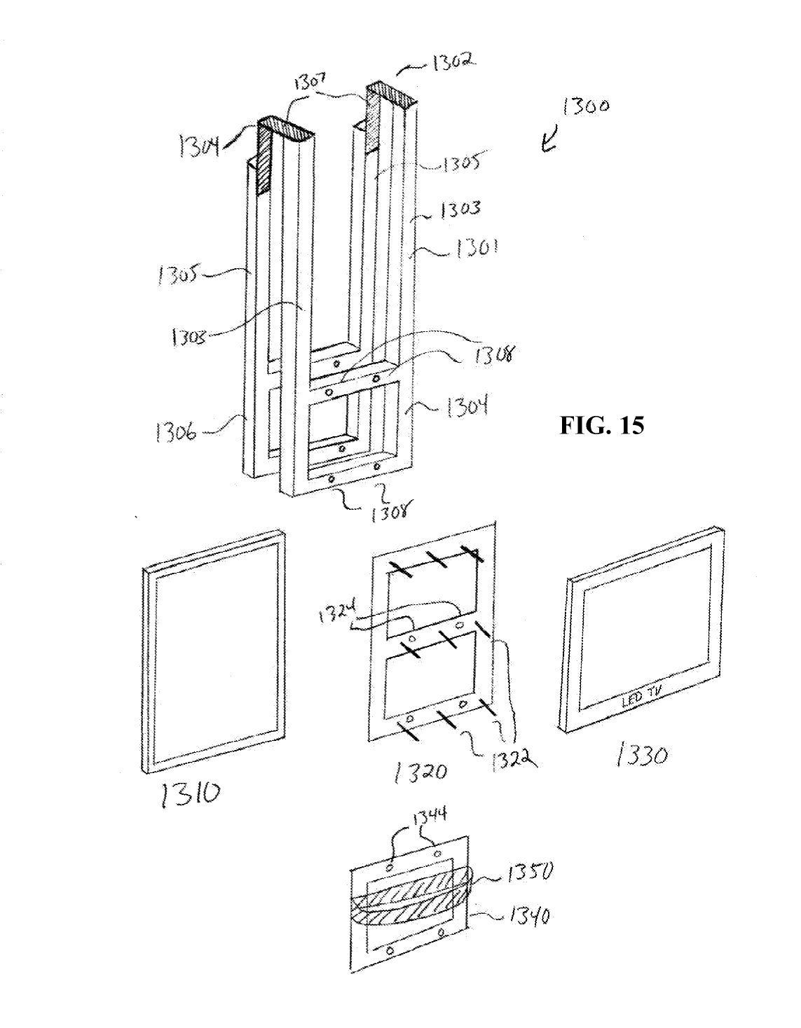

FIG. 15 illustrates an exemplary configurable inverted-U-shaped frame including elongated support members configured to extend down both sides of a panel and generic attachment portions attached to each elongated support member configured to receive modularized attachments. Configuration 1300 includes configurable inverted-U-shaped frame 1301 including attachment members 1302 and 1304 configured to hang upon a top of a panel. The panel can include a partition wall, a panelized door, or any other similar panel. Elongated support members 1303 are illustrated attached to attachment member 1302 and 1304 and are configured to extend along a close side of a panel. Elongated support members 1305 are illustrated attached to attachment member 1302 and 1304 and are configured to extend along a far side of a panel. Attachment members 1302 and 1304 are illustrated including optional thin plate construction 1307, for example including thin steel members 0.5 mm to 2.0 mm thick, for example, to enable a door panel to be closed against a door jam without the attachment members 1302 and 1304 stopping the door from fully seating against the door jam. Generic attachment portions 1304 and 1306 are illustrated on either side of the frame 1301, including attachment points 1308 enabling any of a group of modularized attachments 1310, 1320, 1330 and 1340 to be selectably attached to the frame 1301.

Any of a number of attachments are envisioned for use as modularized attachments to frame 1301. An exemplary mirror 1310 is illustrated, including attachment mechanisms on a rear side of the mirror enabling attachment to attachment points 1308. An exemplary tie and belt rack 1320 is illustrated, including tie and belt posts 1322 and attachment holes 1324 enabling attachment by exemplary screws or bolts to attachment points 1308. An exemplary television 1330 is illustrated, including attachment mechanisms on a rear side of the television enabling attachment to attachment points 1308. An exemplary spice rack 1340 is illustrated, including one exemplary basket 1350 and attachment holes 1344 enabling attachment to attachment points 1308. One basket 1350 is provided for illustration, although it will be realized that a plurality of baskets can be hung upon rack 1340. The illustrated modularized attachments 1310, 1320, 1330, and 1340 are provided as examples. Other similar attachments are envisioned, such as coat racks, toothbrush racks, spice racks located upon both sides of a pantry door, and racks for pots and pans, and the disclosure is not intended to be limited to the particular examples provided herein. In other examples, a DVD player can be hung on a back side of a door and a television can be hung on a front side of the door. In another example, for example for use in a college dorm room, a clock radio can be hung on the front side of a closet door and a bookshelf can be hung on the back side of the door.

According to one embodiment of the disclosure, an apparatus providing a retrofitable inverted-U-shaped frame configured to hang over a thin top of a panelized restroom stall privacy panel can include a inverted-U-shaped frame including a closed end of the inverted-U-shaped frame configured to hang upon the top of the panelized restroom stall privacy panel, wherein the top the panelized restroom stall privacy panel is configured to be at least sixty six inches above a floor surface; a first handrail member; a first elongated support member connected to the closed end and projecting downward from the closed end to a middle portion of the panel and configured to hang along a first side of the panel and suspend the first hand rail member between thirty three and thirty six inches above the floor surface; a second handrail member; and a second elongated support member connected to the closed end and projecting downward from the closed end to the middle portion of the panel and configured to hang along a second side of the panel and suspend the second hand rail member between thirty three and thirty six inches above the floor surface. This embodiment or similar embodiments of the disclosure can include a second closed end configured to hang upon the top of the panelized restroom stall privacy panel; a third elongated support member connected to the second closed end and projecting downward from the second closed end to the middle portion of the panel and configured to hang along the first side of the panel and suspend the first hand rail member between thirty three and thirty six inches above the floor surface; and a fourth elongated support member connected to the second closed end and projecting downward from the second closed end to the middle portion of the panel and configured to hang along the second side of the panel and suspend the second hand rail member between thirty three and thirty six inches above the floor surface.

According to one embodiment of the disclosure, an apparatus providing a retrofitable inverted-U-shaped frame configured to be hung over a thin top of a panelized door can include a inverted-U-shaped frame including a closed end of the inverted-U-shaped frame configured to hang upon the top of the panelized door; a first suspended attachment; a first elongated support member connected to the closed end, projecting downward from the closed end to a middle portion of the panel, configured to hang along a first side of the panel, and suspend the first suspended attachment between thirty three and thirty six inches above the floor surface; a second suspended attachment; and a second elongated support member connected to the closed end, projecting downward from the closed end to the middle portion of the panel, configured to hang along a second side of the panel, and suspend the second suspended attachment between thirty three and thirty six inches above the floor surface.

Length of the elongated support members of the various embodiments of the disclosure can depend upon the panel upon which the frame is to be hung and the usage of the frame as intended. For example, in a restroom stall, each handrail needs to be suspended at a height consistent with regulations, such as the Americans with Disabilities Act, which requires that such handrails be between 33 and 36 inches above a floor surface. Such embodiment can include adjustable elongated support members or can be provided with several lengths of elongated support members, such that the correct support members to suspend the handrails at the required height can be utilized. In other examples, such as a towel rack or coat rack, elongated support members of six or seven inches in length can be used to hang such objects from a closet door. As shown in FIGS. 11 and 12, elongated support members of at least six inches in length extending down sides of a panel from an inverted-U-shaped frame provide increased stability and prevent accidental dislodging of the frame as compared to a frame including only a shallow U-shaped bracket or a frame with elongated support members only on one side of the panel. Such a stable configuration, such as used in a college dorm or child's room, enables an object such as a television or a stereo to be hung from a closet door with an increased confidence in tight quarters that the delicate electronic object will not be knocked off the door.

The disclosure has described certain preferred embodiments and modifications of those embodiments. Further modifications and alterations may occur to others upon reading and understanding the specification. Therefore, it is intended that the disclosure not be limited to the particular embodiment(s) disclosed as the best mode contemplated for carrying out this disclosure, but that the disclosure will include all embodiments falling within the scope of the appended claims.

1. An apparatus providing a retrofitable inverted-U-shaped frame configured to hang over a top of a panel, the apparatus comprising:
the inverted-U-shaped frame comprising:
a closed end of the inverted-U-shaped frame configured to hang upon the top of the panel;
a first elongated support member projecting downward from the closed end to a middle portion of the panel and configured to hang along a first side of the panel; and
a second elongated support member projecting downward from the closed end to the middle portion of the panel and configured to hang along a second side of the panel;
wherein the elongated support members are each configured to support an attachment.

2. The apparatus of claim 1, further comprising a first handrail attached to the first elongated support member and a second handrail attached to the second elongated support member.

3. The apparatus of claim 2, further comprising the panel, wherein the panel comprises a restroom stall privacy wall configured such that the top of the wall is at least sixty six inches above a floor surface below the wall.

4. The apparatus of claim 1, wherein the panel comprises a panelized door.

5. The apparatus of claim 4, further comprising a first shelf attached to the first elongated member and a second shelf attached to the second elongated member.

6. The apparatus of claim 1, wherein each of the elongated support members is at least six inches long.

7. The apparatus of claim 1, wherein the elongated support members projecting downward from the closed end to the middle portion on each side of the panel are configured to prevent the inverted-U-shaped frame from accidentally dislodging from the panel.

8. An apparatus providing a retrofitable inverted-U-shaped frame configured to hang over a thin top of a panelized restroom stall privacy panel, the apparatus comprising:
the inverted-U-shaped frame comprising:
a closed end of the inverted-U-shaped frame configured to hang upon the top of the panelized restroom stall privacy panel, wherein the top the panelized restroom stall privacy panel is configured to be at least sixty six inches above a floor surface;
a first handrail member;
a first elongated support member connected to the closed end and projecting downward from the closed end to a middle portion of the panel and configured to hang along a first side of the panel and suspend the first hand rail member between thirty three and thirty six inches above the floor surface;
a second handrail member; and
a second elongated support member connected to the closed end and projecting downward from the closed end to the middle portion of the panel and configured to hang along a second side of the panel and suspend the second hand rail member between thirty three and thirty six inches above the floor surface.

9. The apparatus of claim 8, the inverted-U-shaped frame further comprising:
a second closed end configured to hang upon the top of the panelized restroom stall privacy panel;
a third elongated support member connected to the second closed end and projecting downward from the second closed end to the middle portion of the panel and configured to hang along the first side of the panel and suspend the first hand rail member between thirty three and thirty six inches above the floor surface; and
a fourth elongated support member connected to the second closed end and projecting downward from the second closed end to the middle portion of the panel and configured to hang along the second side of the panel and suspend the second hand rail member between thirty three and thirty six inches above the floor surface.

10. An apparatus providing a retrofitable inverted-U-shaped frame configured to be hung over a thin top of a panelized door, the apparatus comprising:
the inverted-U-shaped frame comprising:
a closed end of the inverted-U-shaped frame configured to hang upon the top of the panelized door;
a first suspended attachment;
a first elongated support member connected to the closed end, projecting downward from the closed end to a middle portion of the panel, configured to hang along a first side of the panel, and suspend the first suspended attachment between thirty three and thirty six inches above the floor surface;
a second suspended attachment; and
a second elongated support member connected to the closed end, projecting downward from the closed end to the middle portion of the panel, configured to hang along a second side of the panel, and suspend the second suspended attachment between thirty three and thirty six inches above the floor surface.

11. The apparatus of claim 10, further comprising the panelized door, wherein the panelized door comprises one of an entry door, a cabinet door, a shower stall door, and a closet door.

12. The apparatus of claim 10, wherein the first suspended attachment comprises a modularized attachment.

13. The apparatus of claim 12, wherein the modularized attachment comprises one of a mirror, a clothing rack, a television set, an electronic device, a hanging basket, a spice rack, and a book shelf.

14. The apparatus of claim 12, wherein the closed end comprises thin sections configured to enable the panelized door to close against a door jam with the inverted-U-shaped frame hanging over the door.

15. The apparatus of claim 14, wherein the thin sections are between 0.5 mm and 2.0 mm thick.

16. The apparatus of claim 10, wherein each of the elongated support members is at least two feet long.

17. The apparatus of claim 10, wherein each of the elongated support members is at least six inches long.
